(19) United States
(12) Patent Application Publication
(10) Pub. No.: US 2016/0276353 A1
(43) Pub. Date: Sep. 22, 2016

(54) NONVOLATILE SEMICONDUCTOR MEMORY DEVICE

(71) Applicant: Kabushiki Kaisha Toshiba, Minato-ku (JP)

(72) Inventors: Shigeki KOBAYASHI, Kuwana (JP); Kei SAKAMOTO, Nagoya (JP); Takamasa OKAWA, Yokkaichi (JP); Ryosuke SAWABE, Yokkaichi (JP)

(73) Assignee: Kabushiki Kaisha Toshiba, Minato-ku (JP)

(21) Appl. No.: 14/816,431

(22) Filed: Aug. 3, 2015

Related U.S. Application Data
(60) Provisional application No. 62/134,638, filed on Mar. 18, 2015.

(51) Int. Cl. H01L 27/115

(52) U.S. Cl. CPC H01L 27/1157; H01L 27/11524; H01L 27/11578; H01L 27/11551

(57) ABSTRACT

A stacked body is disposed so as cover a periphery of a semiconductor columnar portion and includes a conductive layer and an inter-layer insulating layer stacked alternately in a stacking direction on a semiconductor substrate. An epitaxial layer is disposed on a surface of the semiconductor substrate and is electrically connected to a lower end of the semiconductor columnar portion. The semiconductor columnar portion comprises: an insulating film core; and a semiconductor portion disposed so as to cover a periphery of the insulating film core and electrically connected to the epitaxial layer at a lower end portion. The epitaxial layer includes a concave portion in a surface thereof, and the insulating film core has a lower end thereof positioned inside the concave portion.

### CROSS REFERENCE TO RELATED APPLICATIONS

This application is based on and claims the benefit of priority from prior US prior provisional Patent Application No. 62/134,638, filed on Mar. 18, 2015, the entire contents of which are incorporated herein by reference.

### FIELD

Embodiments described below relate to a nonvolatile semiconductor memory device.

### BACKGROUND

In recent years, in the field of NAND type flash memory, a stacked type (three-dimensional type) NAND type flash memory has been attracting attention as a device capable of achieving a high degree of integration without being limited by a resolution limit of lithography technology.

In such a three-dimensional type NAND type flash memory, ON/OFF characteristics (selection characteristics) of a select transistor are important, and it is required to pass a sufficient cell current during selection (during ON). On the other hand, during non-selection (OFF), it is desired that a leak current of the select transistor is made as small as possible.

### BRIEF DESCRIPTION OF THE DRAWINGS

FIG. 1 is a perspective view showing schematically an example of a structure of a nonvolatile semiconductor memory device 100 of an embodiment of the present invention.

FIG. 2 is a perspective view showing a structure of part of a memory cell array 11.

FIG. 3 is an equivalent circuit diagram of one NAND cell unit NU.

FIG. 4A is a perspective cross-sectional view of one memory cell MC.

FIG. 4B is a schematic view of one source side select transistor S2.

FIG. 5 is a plan view of part of the memory cell array 11.

FIG. 6 is a cross-sectional view along part of a Y direction of the memory cell array 11 (a cross-sectional view of the X-X′ direction of FIG. 5).

FIGS. 7 to 15 are process drawings showing a method of manufacturing the memory cell MC.

FIG. 16 is a cross-sectional view showing an example of the structure of the nonvolatile semiconductor memory device 100 of the embodiment of the present invention.

### DETAILED DESCRIPTION

A nonvolatile semiconductor memory device according to an embodiment described below comprises: a semiconductor substrate; a semiconductor columnar portion extending in a perpendicular direction to the semiconductor substrate; a memory gate insulating layer covering a side surface of the semiconductor columnar portion; a stacked body disposed so as cover a periphery of the semiconductor columnar portion and including a conductive layer and an inter-layer insulating layer stacked alternately in a stacking direction on the semiconductor substrate; and an epitaxial layer disposed on a surface of the semiconductor substrate and disposed so as to be electrically connected to a lower end of the semiconductor columnar portion. The semiconductor columnar portion comprises: an insulating film core; and a semiconductor portion disposed so as to cover a periphery of the insulating film core and electrically connected to the epitaxial layer at a lower end portion. The epitaxial layer includes a concave portion in a surface thereof, and the insulating film core has a lower end thereof positioned inside the concave portion.

Next, nonvolatile semiconductor memory devices according to embodiments will be described in detail with reference to the drawings. Note that these embodiments are merely examples, and are not shown with the intention of limiting the present invention. Moreover, each of the drawings of the nonvolatile semiconductor memory devices employed in the embodiments below is schematic, and thicknesses, widths, ratios, and so on, of layers differ from those of the actual nonvolatile semiconductor memory devices.

The embodiments below relate to a nonvolatile semiconductor memory device having a structure in which a plurality of MONOS type (Metal-Oxide-Nitride-Oxide-Semiconductor) memory cells (memory transistors) are provided in a height direction, each of the MONOS type memory cells including: a semiconductor layer acting as a channel provided in a column shape perpendicularly to a substrate; and a gate electrode layer provided on a side surface of the semiconductor layer via a charge accumulation layer. However, this also is not intended to limit the present invention, and the present invention may be applied also to a memory cell of another form of charge accumulation layer, for example, a SONOS type (Semiconductor-Oxide-Nitride-Oxide-Semiconductor) memory cell or a floating gate type memory cell.

### First Embodiment

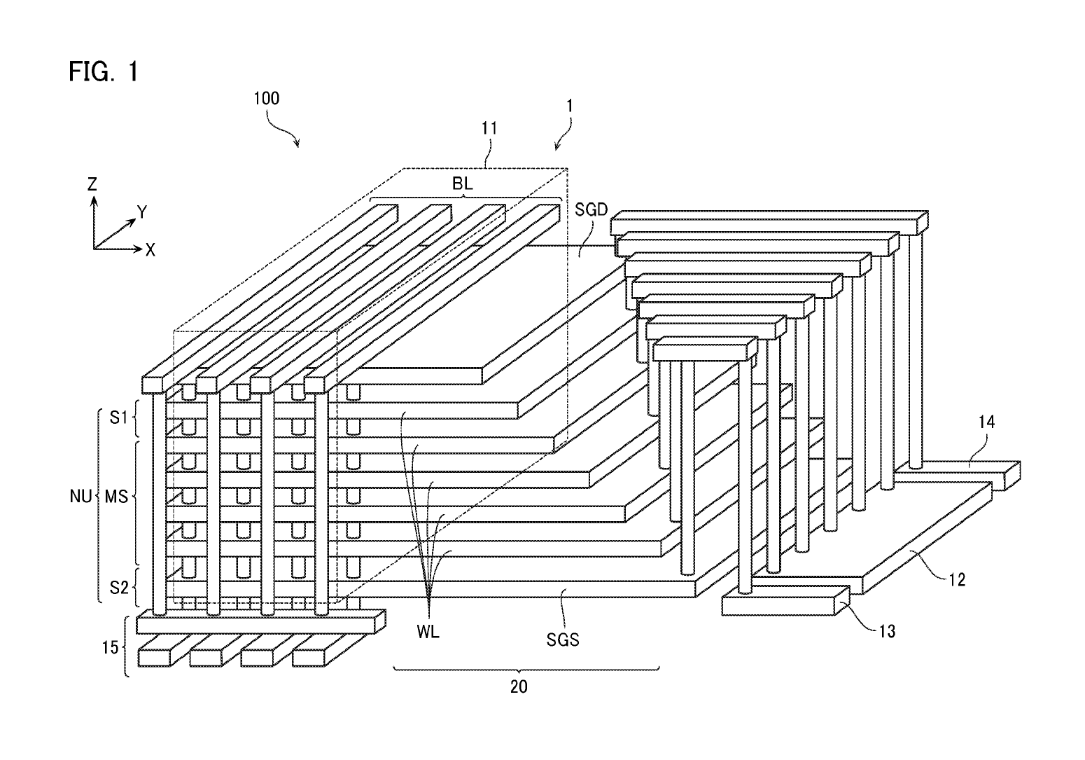

FIG. 1 is a perspective view showing schematically an example of a structure of a nonvolatile semiconductor memory device 100 of a first embodiment. Description below will proceed based on a rectangular coordinate system assuming directions along a semiconductor substrate to be an X direction and a Y direction, and a direction orthogonal to a principal plane of the semiconductor substrate to be a Z direction.

The nonvolatile semiconductor memory device 100 includes: a memory cell array 11; a word line drive circuit 12; a source side select gate line drive circuit 13; a drain side select gate line drive circuit 14; a sense amplifier 15; a word line WL; a source side select gate line SGS; a drain side select gate line SGD; a bit line BL; a word line wiring line portion, and so on.

The memory cell array 11 comprises the following, on a semiconductor substrate (not illustrated in FIG. 1), namely: a memory string MS having a plurality of memory cells MC (memory transistors) connected in series therein; and a drain side select transistor S1 and a source side select transistor S2 respectively connected to both ends of the memory string MS. Note that the memory string MS and the drain side select transistor S1 and source side select transistor S2 connected to both ends of the memory string MS will be referred to below as “NAND cell unit NU”.

As will be mentioned later, the memory cell MC has a structure in which a control gate electrode (word line) is provided, via a memory layer including a charge accumulation layer, on a side surface of a columnar semiconductor film acting as a channel; and the drain side select transistor S1 and source side select transistor S2 have a structure in which a select gate electrode (select gate line) is provided, via a gate insulating film, on a side surface of a columnar semiconductor portion. To simplify illustration, FIG. 1 illustrates only four memory cells MC in one memory string MS, but the number of memory cells MC in one memory string MS may of course be set to more than four. The same applies also to the other drawings.

The word line WL is commonly connected to memory cells adjacent in the XY plane. Moreover, similarly, the source side select gate line SGS is also commonly connected to source side select transistors S2 adjacent in the XY plane, and similarly, the drain side select gate line SGD is also commonly connected to drain side select transistors S1 adjacent in the XY plane.

Note that in the description below, the source side select gate line SGS and the drain side select gate line SGD are sometimes collectively written simply as “select gate line”. Moreover, the source side select transistor and the drain side select transistor are sometimes collectively written simply as “select transistor”.

In addition, sometimes, one or a plurality of the memory cells MC close to the source side select gate line SGS and the drain side select gate line SGD, of the memory cells MC in the memory string MS, is treated as a dummy cell not employed in data storage. In the example described below, one dummy cell is respectively provided to both ends of the memory string MS, but the present invention is not intended to be limited to this configuration and there may be two or more dummy cells, moreover, it is also possible for the dummy cell to be omitted. Note that it is also possible for a plurality of the drain side select transistors S1 and/or the source side select transistors S2 to be connected to one memory string MS. To simplify description, an example where one drain side select transistor S1 and one source side select transistor S2 are connected to one memory string MS is mainly described below.

Furthermore, the bit lines BL are disposed so as to extend having the Y direction that intersects the X direction as their longer direction, and are arranged with a certain pitch in the X direction. The bit line BL is connected to a plurality of the memory strings MS via the drain side select transistor S1. Although illustration thereof is omitted in FIG. 1, a source line SL is similarly disposed having the Y direction as its longer direction, and is connected to the memory string MS via the source side select transistor S2.

The word line drive circuit 12 is a circuit that controls a voltage applied to the word line WL; and the source side select gate line drive circuit 13 is a circuit that controls a voltage applied to the source side select gate line SGS. Furthermore, the drain side select gate line drive circuit 14 is a circuit that controls a voltage applied to the drain side select gate line SGD. Moreover, the sense amplifier 15 is a circuit that amplifies a signal (voltage) read in the bit line BL from a selected memory cell.

A wiring line portion 20 is a wiring line portion for connecting the word line WL and the select gate lines SGD and SGS to a contact. The word line WL and the select gate lines SGS and SGD have a structure of being processed in steps so as to each be capable of being connected to the contact independently at their upper portions.

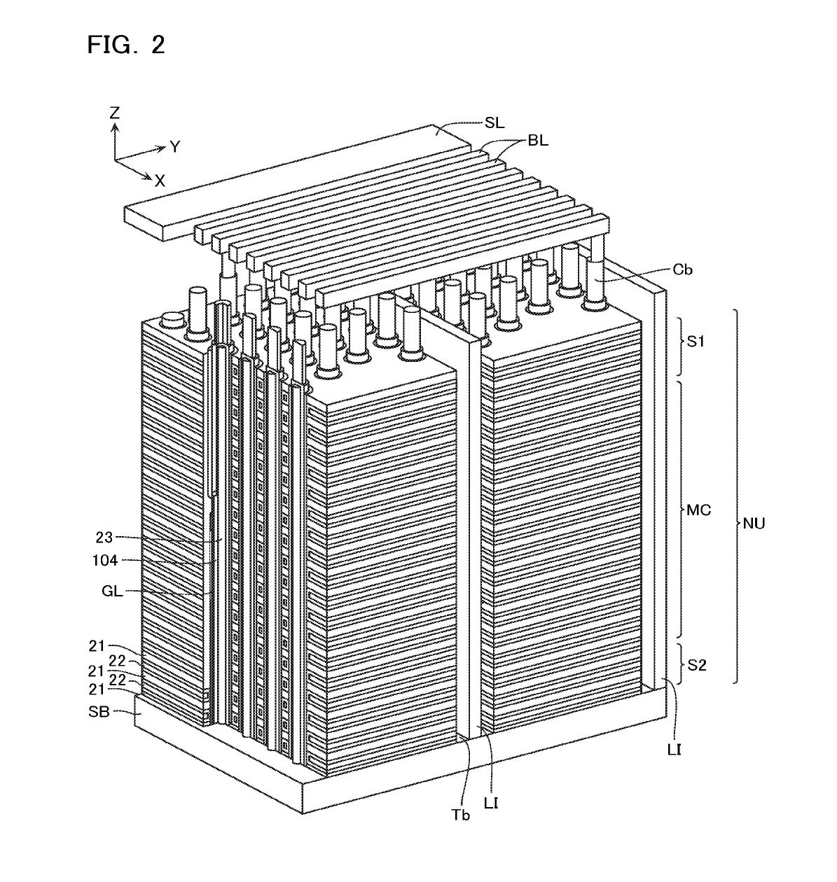

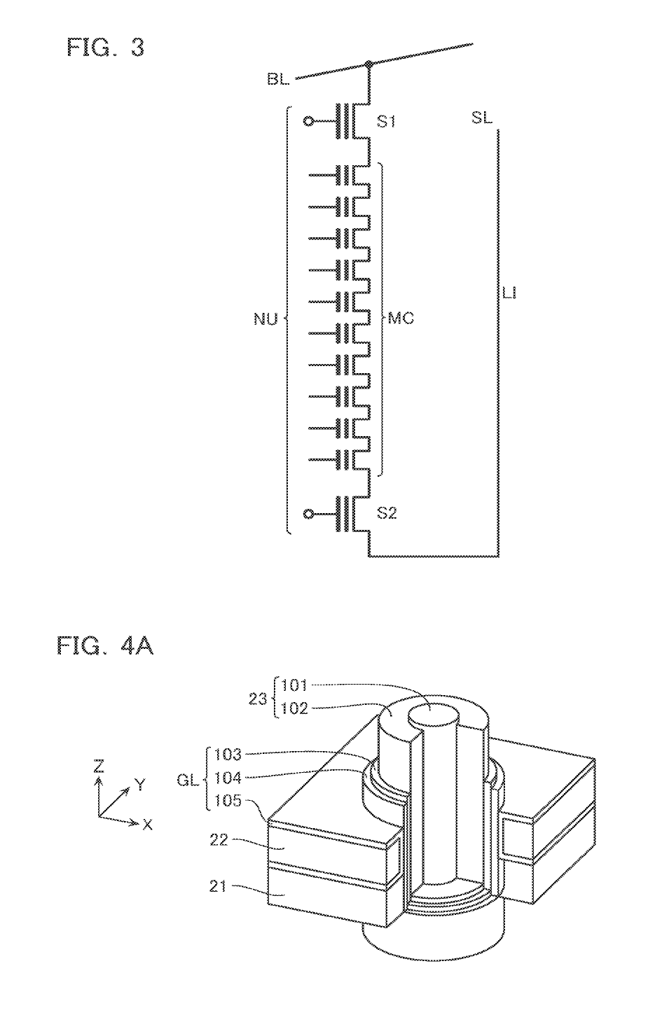

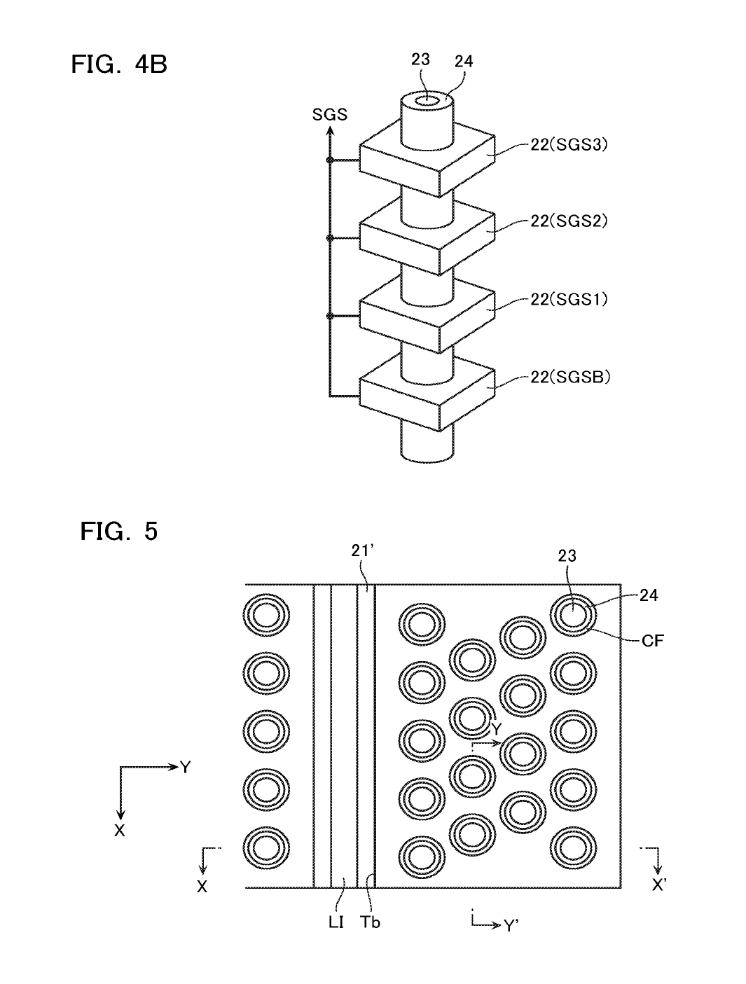

Next, details of a structure of the memory cell array 11 will be described with reference to FIGS. 2 to 4A. FIG. 2 is a perspective view showing a structure of part of the memory cell array 11; FIG. 3 is an equivalent circuit diagram of one NAND cell unit NU; and FIG. 4A is a perspective cross-sectional view of one memory cell MC, and so on.

As shown in FIG. 2, the memory cell array 11 has a structure in which an inter-layer insulating film 21 and a conductive layer 22 are stacked alternately on a semiconductor substrate SB configured from monocrystalline silicon. This conductive layer 22 functions as a control gate of the memory cell MC (word line WL), as the source side select gate line SGS, or as the drain side select gate line SGD. The inter-layer insulating film 21 is disposed above and below these conductive layers 22, and electrically insulates fellow conductive layers 22.

The conductive layer 22 may be formed by, for example, tungsten (W), tungsten nitride (WN), tungsten silicide (WSix), tantalum (Ta), tantalum nitride (TaN), tantalum silicide (TaSix), palladium silicide (PdSix), erbium silicide (ErSix), yttrium silicide (YSix), platinum silicide (PtSix), hafnium silicide (HfSix), nickel silicide (NiSix), cobalt silicide (CoSix), titanium silicide (TiSix), vanadium silicide (VSix), chromium silicide (CrSix), manganese silicide (MnSix), iron silicide (FeSix), ruthenium (Ru), molybdenum (Mo), titanium (Ti), titanium nitride (TiN), vanadium (V), chromium (Cr), manganese (Mn), iron (Fe), cobalt (Co), nickel (Ni), gold (Au), silver (Ag), or copper (Cu), or by a compound of these. However, the conductive layer 22 may also be formed by polysilicon to which an impurity is added.

Moreover, as shown in FIG. 2, semiconductor layers 23 are arranged with a certain pitch in the XY plane having a stacking direction (Z direction of FIG. 2) as their longer direction, so as to penetrate a stacked body of such an inter-layer insulating film 21 and conductive layer 22. This semiconductor layer 23 functions as a channel region (body) of the memory cell MC and the select transistors S1 and S2 included in the NAND cell unit NU. Formed between the semiconductor layer 23 and the stacked body of the conductive layer 22 and the inter-layer insulating film 21 is a memory layer GL that includes the charge accumulation layer. The memory layer GL may be formed from a stacked structure of the charge accumulation layer of the likes of a silicon nitride film, and an oxide film of the likes of a silicon oxide film. A threshold voltage of the memory cell MC changes by an accumulated amount of charge to this charge accumulation layer, and the memory cell MC stores data corresponding to this threshold voltage.

These semiconductor layers 23 are connected at their upper ends to the bit line BL via a contact Cb. The bit lines BL are arranged with a certain pitch in the X direction having the Y direction as their longer direction.

In addition, a lower end of the semiconductor layer 23 is electrically connected to the semiconductor substrate SB. The lower end of the semiconductor layer 23 is connected to the source line SL via a later-to-be-described epitaxial layer 108 (not illustrated in FIG. 2), the semiconductor substrate SB, a later-to-be-described source contact LI, and an unillustrated contact formed on the source contact LI. The source lines SL are arranged having the Y direction as their longer direction, similarly to the bit line BL.

Note that the stacked body of the inter-layer insulating film 21 and the conductive layer 22 in the memory cell array 11 is divided on a block-by-block basis, the block being a minimum unit of data erase. A trench Tb is formed at a boundary of division, this trench Tb is implanted with an unillustrated inter-layer insulating film, and the previously mentioned source contact LI is further formed penetrating that inter-layer insulating film. This source contact LI has its lower end connected to the semiconductor substrate SB while having its upper end connected to the source line SL.

FIG. 3 is an equivalent circuit diagram of one NAND cell unit NU. One NAND cell unit NU comprises: the memory string MS configured from a series-connected circuit of a plurality of the memory cells MC; the drain side select transistor S1 connected between the bit line BL and an upper end of the memory string MS; and the source side select transistor S2 connected between the source line SL and a lower end of the memory string MS.

An example of a specific structure of one memory cell MC is shown in FIG. 4A. The semiconductor layer 23 comprises: an insulating film core 101; and a columnar semiconductor portion (semiconductor columnar portion) 102 surrounding a periphery of the insulating film core 101. The insulating film core 101 is configured from, for example, silicon oxide (SiO₂); and the semiconductor columnar portion 102 is configured by, for example, polysilicon, but may also be configured from the likes of monocrystalline silicon (Si), silicon-germanium (SiGe), silicon carbide (SiC), germanium (Ge), or carbon (C), instead of polysilicon. Moreover, the semiconductor columnar portion 102 may be formed as a single-layer structure of any of the above-described substances, or may be formed as a stacked structure of two or more different kinds of the substances. In the case where the number of stacked conductive layers 22 increases and a height of the stacked body becomes large, polysilicon is preferably adopted in view of implanting characteristics.

Formed in a periphery of this semiconductor columnar portion 102 so as to surround the semiconductor columnar portion 102 are a tunnel insulating layer 103, a memory layer 104 (charge accumulation layer), and a block insulating layer 105. The tunnel insulating layer 103, the memory layer 104, and the block insulating layer 105 configure a memory gate insulating layer GL. The tunnel insulating layer 103 is configured from, for example, a silicon oxide film (SiOx), and functions as a tunnel insulating layer of the memory cell MC. The memory layer 104 includes, for example, a silicon nitride film (SiN), and functions to trap (accumulate) electrons injected via the tunnel insulating layer 103 from the semiconductor columnar portion 102 by a write operation. The block insulating layer 105 may be formed from, for example, a silicon oxide film. In this example, the block insulating layer 105 differs from the tunnel insulating layer 103 and the memory layer 104, and is formed so as to surround a periphery of the conductive layer 22.

The above-described tunnel insulating layer 103, memory layer 104, and block insulating layer 105 are referred to collectively as the memory gate insulating layer GL. In the case of FIG. 4A, the memory gate insulating layer GL is expressed by three layers. Regarding number or order, materials, and so on, of layers of the memory gate insulating layer GL, a variety of combinations are conceivable, but the memory gate insulating layer GL includes at least the above-described memory layer 104.

Note that also employable as a material of the tunnel insulating layer 103 and the block insulating layer 105, besides a silicon oxide film (SiOx), are, for example, Al₂O₃, Y₂O₃, La₂O₃ Gd₂O₃, Ce₂O₃, CeO₂, Ta₂O₅, HfO₂, ZrO₂, TiO₂, HfSiO, HfAlO, ZrSiO, ZrAlO, AlSiO, and so on.

FIG. 4B shows a structure of the source side select transistor S2. As shown in FIG. 4B, the source side select transistor S2 comprises a single select gate line SGS (gate electrode) configured by short-circuiting a plurality of the conductive layers 22 (referred to from above as conductive layers SGS3, SGS2, SGS1, and SGSB). Having the gate electrode configured by a plurality of the conductive layers 22 in this way is preferable from the viewpoint of improving selection characteristics (increasing an ON current during ON operation, and reducing a leak current during OFF) of the select transistor S2. A structure of the drain side select transistor S1 is also substantially similar, hence description thereof will be omitted. However, it goes without saying that the number of conductive layers 22 included in one select transistor S1 or S2 can be selected freely and is not limited to a specific number.

FIG. 5 is a plan view of part of the memory cell array 11. As shown in FIG. 5, the semiconductor layers 23 are arranged so as to be aligned in a direction oblique to the X direction (word line direction) and the Y direction (bit line direction), whereby an arrangement density of the semiconductor layers 23 is increased, and an arrangement density of the memory cells MC is raised. However, this is merely an example, and it is also possible to configure such that the semiconductor layers 23 are aligned along the X direction and the Y direction. Moreover, the source contact LI is formed in a stripe, for example, having the X direction as its longer direction, and is implanted in the trench Tb via an inter-layer insulating film 21′. The striped shape is merely an example, and a variety of shapes of the source contact LI may be adopted, provided that the source contact LI enables connection between the substrate SB and the source line SL.

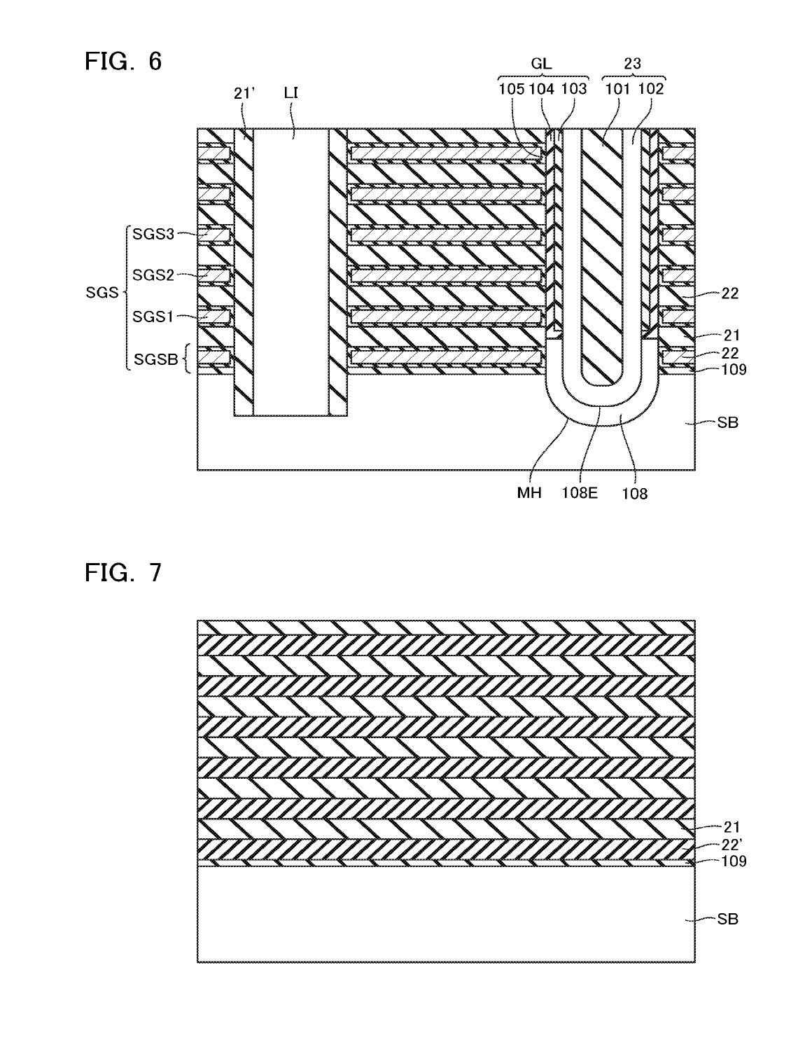

FIG. 6 is a cross-sectional view taken along the line X-X′ of FIG. 5, and is a cross-sectional view including the memory cell MC and the source contact LI. Formed on the semiconductor substrate SB that has a gate oxide film 109 formed on its outer surface is the semiconductor columnar portion 102, the semiconductor columnar portion 102 being formed extending in a perpendicular direction to the substrate SB. Formed on a side surface of the semiconductor columnar portion 102 is the memory gate insulating layer GL that includes the charge accumulation layer. Further formed around the semiconductor columnar portion 102, via the memory gate insulating layer GL, is the conductive layer 22. The conductive layers 22 are stacked on the substrate SB sandwiching the inter-layer insulating layer 21 between them.

Moreover, the epitaxial layer 108 is formed so as to surround a lower end of the semiconductor columnar portion 102. The epitaxial layer 108 is, for example, a silicon layer of single crystals that may be formed by epitaxial growth using as an underlayer the semiconductor substrate SB configured from monocrystalline silicon. In the case of using the semiconductor substrate SB as an underlayer, the epitaxial layer 108 becomes a monocrystalline silicon layer formed continuously from the semiconductor substrate SB.

Contrary to the epitaxial layer 108, the semiconductor columnar portion 102 is usually formed by polysilicon which is different from monocrystalline silicon. In this case, a crystal grain boundary does not exist in the epitaxial layer 108, and a current may be more easily passed compared to in the semiconductor columnar portion 102.

A lower end of the epitaxial layer 108 is positioned lower than a surface of the substrate SB. On the other hand, an upper surface of the epitaxial layer 108 is positioned at least higher than an upper surface of the lowermost layer conductive layer SGSB of the plurality of conductive layers 22 configuring the select gate line SGS (refer to FIG. 6). It is also possible to configure such that the upper surface of the epitaxial layer 108 is positioned higher than an upper surface of an even higher layer conductive layer SGS3, SGS2, or SGS1.

Such an epitaxial layer 108 is configured for the following reason. Due to progress of miniaturization, in the case of forming a memory hole MH for forming the semiconductor layer 23, it is generally difficult to stop processing of that memory hole MH close to the surface of the substrate SB, and the memory hole MH ends up digging deeply into the surface of the substrate SB. In the case that the memory hole MH has ended up digging deeply into the surface of the substrate SB, there is a risk that if the semiconductor layer 23 configured from the likes of polysilicon is formed in that memory hole unchanged in such a state, a resistance value of the memory string MS ends up increasing and a cell current ends up being reduced.

Accordingly, in the present embodiment, the above-mentioned kind of epitaxial layer 108 is formed in a bottom of the memory hole MH, and the semiconductor layer 23 is electrically connected to the substrate SB via this epitaxial layer 108. As a result of such an epitaxial layer 108 that has a monocrystalline structure being formed in the memory hole MH formed by digging deeply into the substrate SB, an increase in the resistance value of the memory string MS can be suppressed and a lowering of the cell current can be prevented.

Moreover, the epitaxial layer 108 of the present embodiment includes a concave portion 108E close to the center of its upper end. Lower end portions of the insulating film core 101 and the semiconductor columnar portion 102 are formed so as to penetrate inside this concave portion 108E. The semiconductor columnar portion 102 is disposed at a position between the epitaxial layer 108 and the insulating film core 101, inside the concave portion 108E.

The concave portion 108E is configured such that at least a lower end of the insulating film core 101 reaches any one of the plurality of conductive layers 22 configuring the select gate line SGS. In the illustrated example, the lower end of the insulating film core 101 reaches the lowermost layer conductive layer SGSB (has an end portion at a position of the conductive layer SGSB).

As a result of the concave portion 108E and the insulating film core 101 being formed in this way, a current flowing in the source side select transistor S2 is limited to close to the gate electrode. This makes it possible for the leak current during OFF of the select transistor S2 to be reduced. In the case that the epitaxial layer 108 does not include the concave portion 108E, and the whole of the base of the memory hole MH is filled by the epitaxial layer 108, a current may also flow close to the center of the memory hole MH. In this case, the OFF leak current of the select transistor S2 cannot be sufficiently reduced. Due to the present embodiment, the insulating film core 101 can be formed close to the center of the epitaxial layer 108, hence a current can be prevented from flowing close to the center of the memory hole MH, and the OFF leak current during OFF of the select transistor S2 can be reduced.

Note that in the illustrated example, the lower end of the insulating film core 101 reaches the lowermost layer conductive layer SGSB, but the present embodiment is not intended to be limited to this configuration. It is also possible to adopt instead a configuration in which, for example, the lower end of the insulating film core 101 reaches at least one of the conductive layers SGS1 through SGS3, but does not reach the conductive layer SGSB. In this case also, the leak current during OFF of the source side select transistor S2 can be sufficiently suppressed.

This epitaxial layer 108 may be formed by an epitaxy method using the substrate SB as an underlayer (homo-epitaxial growth), but may be formed also by an epitaxy method employing a material different from that of the substrate SB (hetero-epitaxial growth). In the case of hetero-epitaxial growth, an unillustrated buffer layer may be disposed between the epitaxial layer 108 and the substrate SB. By configuring in this way, the epitaxial layer 108 becomes electrically connected to each of the substrate SB and the semiconductor columnar portion 102, resulting in electrical contact being achieved between the semiconductor columnar portion 102 and the substrate SB.

Moreover, the previously mentioned source contact LI is implanted via the inter-layer insulating film 21′ in the trench Tb dividing the memory cell array 11. Although illustration thereof is omitted, the source contact LI may also be formed such that its lower end electrically contacts the substrate SB via a diffusion layer (not illustrated) formed in the surface of the substrate SB.

[Method of Manufacturing Memory Cell MC]

Next, a method of manufacturing the memory cell MC will be described with reference to FIGS. 7 to 15.

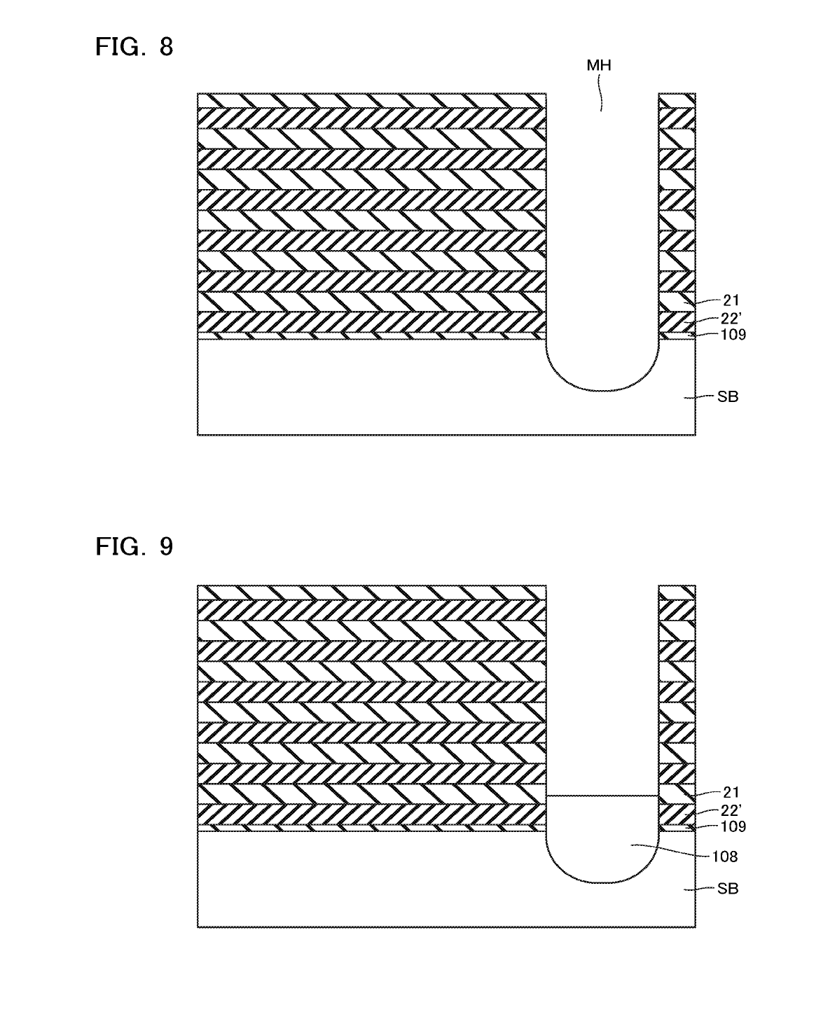

First, as shown in FIG. 7, the gate insulating film 109 configured from the likes of a silicon oxide film is formed on the substrate SB configured from the likes of silicon, and a sacrifice film 22′ configured from a silicon nitride film and the inter-layer insulating film 21 configured from, for example, a silicon oxide film are stacked alternately to form the stacked body. Then, as shown in FIG. 8, the memory hole MH penetrating the stacked body and the gate insulating film 109 is formed by anisotropic etching such as RIE. RIE is continued until a bottom surface of this memory hole MH penetrates the gate insulating film 109 to be positioned lower than the surface of the substrate SB.

Then, as shown in FIG. 9, the epitaxial layer 108 is formed in the base of the memory hole MH. As mentioned previously, the epitaxial layer 108 may be formed by employing homo-epitaxial growth where silicon of the substrate SB is used as an underlayer or hetero-epitaxial growth where a material different from that of the substrate SB is used as an underlayer layer.

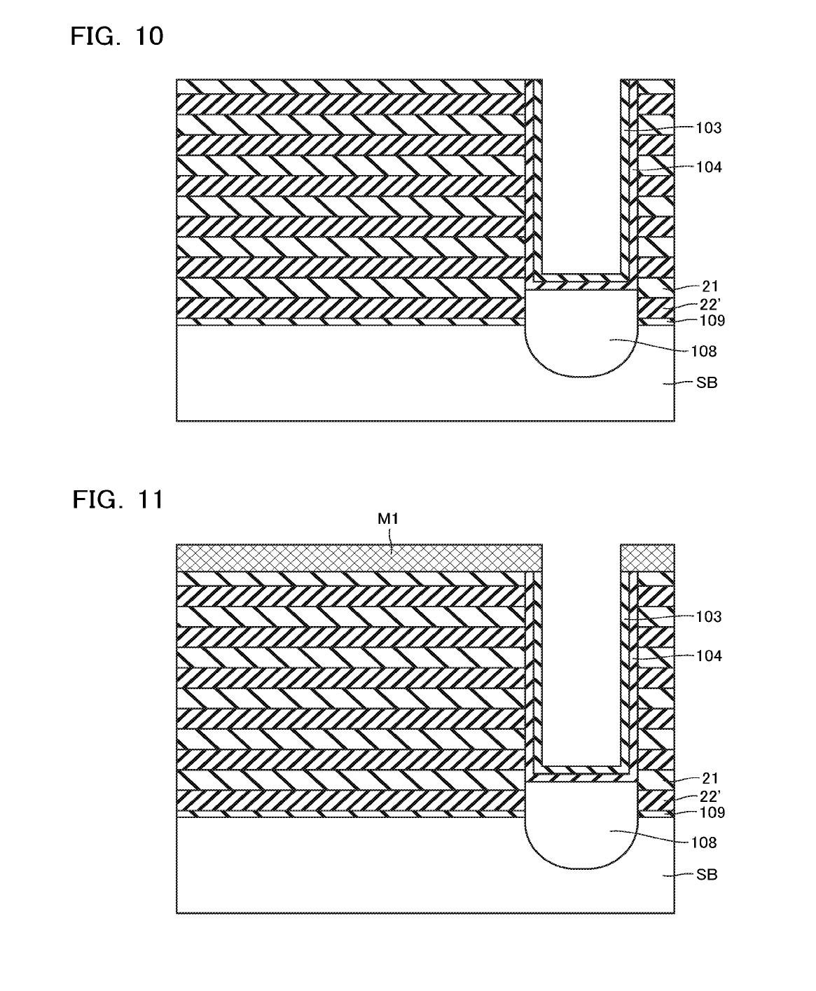

Next, as shown in FIG. 10, the previously mentioned memory layer 104 and tunnel insulating layer 103 are deposited by a CVD method, and so on, in a layer higher than the epitaxial layer 108 of an inner wall of the memory hole MH, thereby forming part of the memory gate insulating layer GL. It is also possible to additionally deposit a cover film at this time, in order to avoid the tunnel insulating film 103 being damaged by later-to-be-described RIE. Polysilicon is given as an example of a material of the cover film. In this case, the polysilicon of the cover film does not need to be peeled after RIE and may also be used as part of the semiconductor columnar portion 102.

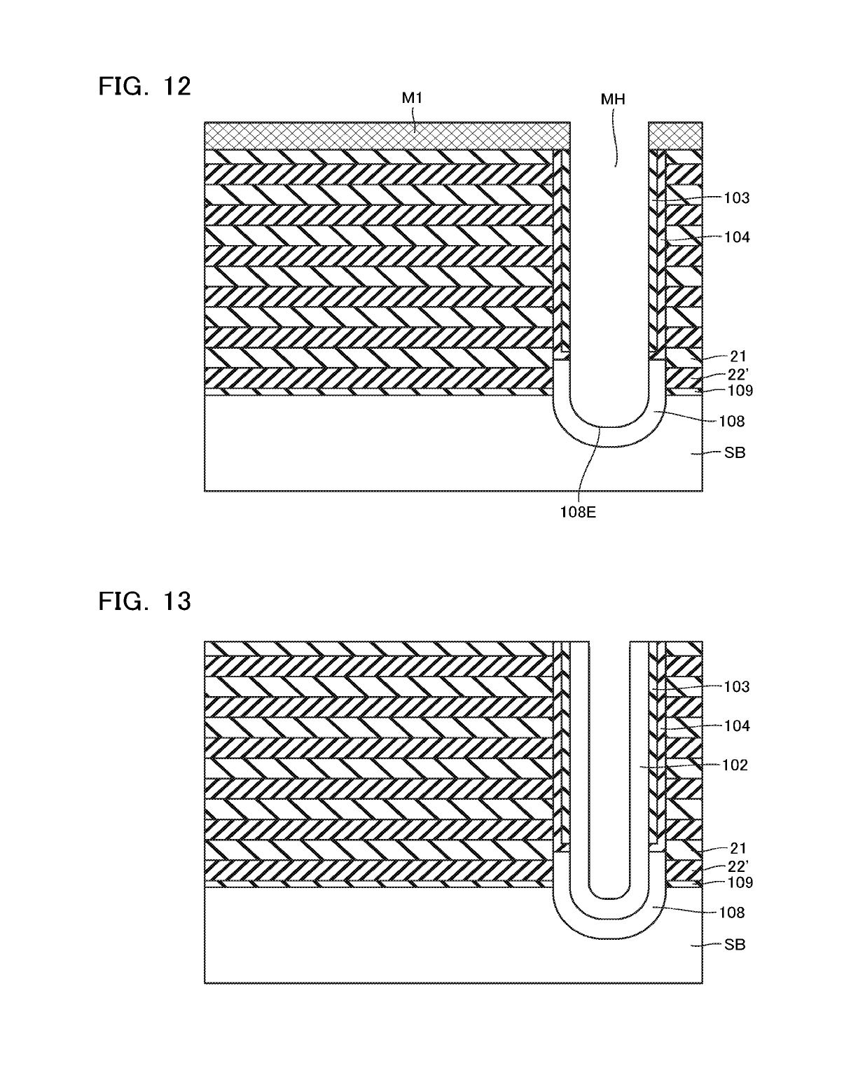

Subsequently, as shown in FIG. 11, a mask material M1 is formed on a surface of the uppermost layer inter-layer insulating film 21. As shown further in FIG. 12, RIE using the mask material M1 as a mask is performed, whereby the memory layer 104 and the tunnel insulating layer 103 on the surface of the epitaxial layer 108 are removed by etching and the previously mentioned concave portion 108E is formed.

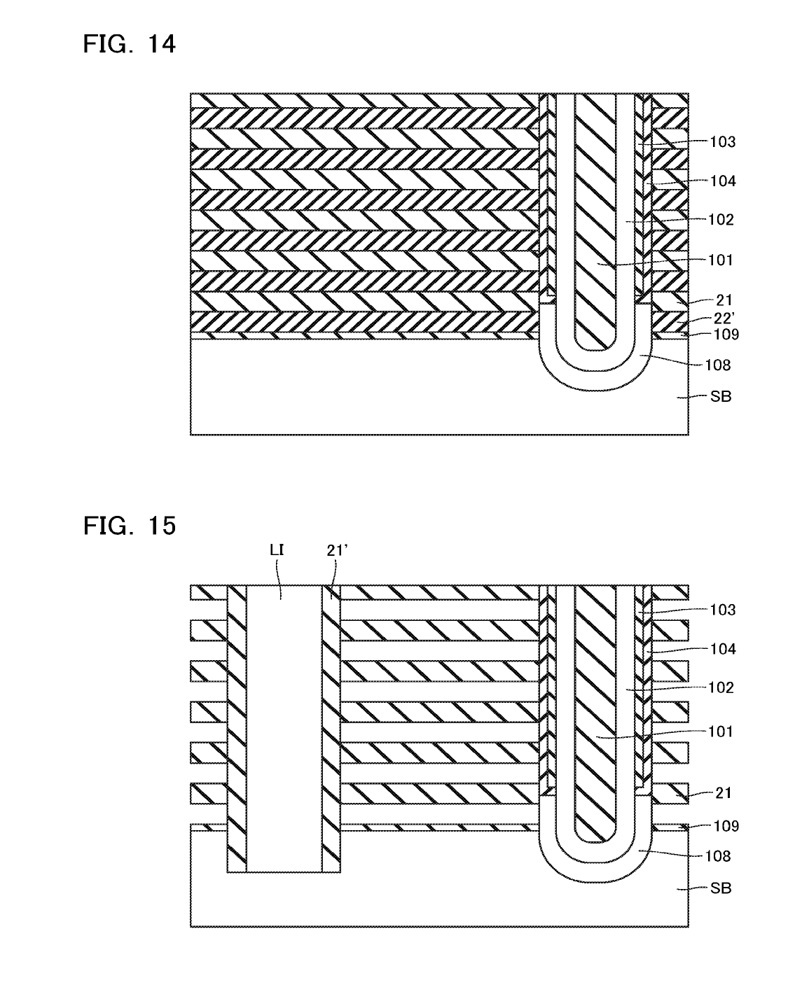

Subsequently, as shown in FIG. 13, polysilicon is deposited along a sidewall of the tunnel insulating layer 103 and an inner wall of the epitaxial layer 108 (including inside the concave portion 108E) by a CVD method, thereby forming the previously mentioned semiconductor layer 102. Then, as shown in FIG. 14, the insulating film core 101 is further deposited on an inner wall of the semiconductor layer 102.

Then, as shown in FIG. 15, the sacrifice film 22′ of the stacked body is removed by the likes of wet etching or dry etching. An air gap caused by etching of this sacrifice film 22′ has CVD executed thereon, thereby forming the previously mentioned block insulating film 105 along a sidewall of the air gap, and a conductive film of tungsten or the like is further deposited to form the conductive layer 22. Subsequently, excess conductive film deposited in the trench is removed, and an insulating film is deposited in the trench. Next, a lower portion of the insulating film is removed by RIE, and the source contact LI is formed in a state where electrical connection with the substrate SB has been secured. As a result, the configuration of FIG. 6 is completed.

[Charge Accumulation Layer]

In the above described embodiment, a silicon nitride film (SiN) was given as an example of a material of the charge accumulation layer included in the memory layer 104. However, the following oxides may also be selected as the material of the charge accumulation layer, namely:

SiO2, Al₂O₃, Y₂O₃, La₂O₃ Gd₂O₃, Ce₂O₃, CeO₂, Ta₂O₅, HfO₂, ZrO₂, TiO₂, HfSiO, HfAlO, ZrSiO, ZrAlO, AlSiO;

AB₂O₄ (where A and B are the same or different elements, and are one of Al, Sc, Ti, V, Cr, Mn, Fe, Co, Ni, Cu, Zn, Ga, and Ge; for example, Fe₃O₄, FeAl₂O₄, Mn_{1|x}Al₂₋ₓO_{4|y}, CO_{1|x}Al₂₋ₓO_{4|y}, MnOx, and so on); and

ABO₃ (where A and B are the same or different elements, and are one of Al, La, Hf, Ta, W, Re, Os, Ir, Pt, Au, Hg, Tl, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn; for example, LaAlO₃, SrHfO₃, SrZrO₃, SrTiO₃, and so on).

Moreover, the following oxynitrides may also be selected as the material of the charge accumulation layer, namely:

SiON, AlON, YON, LaGN, GdON, CeON, TaON, HfON, ZrON, TiON, LaAlON, SrHfON, SrZrON, SrTiON, HfSiON, HfAlON, ZrSiON, ZrAlON, and AlSiON.

Furthermore, it is also possible to adopt a material in which some of the oxygen elements of the above-described oxides are substituted by a nitrogen element. Specifically, single and multiple insulating layers are each preferably selected from the group of SiO₂, SiN, Si₃N₄, Al₂O₃, SiON, HfO₂, HfSiON, Ta₂O₅, TiO₂, and SrTiO₃.

Specifically, concentrations of oxygen elements and nitrogen elements in silicon system insulating films such as SiO₂, SiN, SiON may each be set to 1×10¹⁸ atoms/cm³ or more. However, barrier heights of the multiple insulating layers differ from each other. Moreover, the insulating layer may include a material that includes an impurity atom forming a defect level or a semiconductor/metal dot (quantum dot).

### Advantages of First Embodiment

As described above, due to the present embodiment, the epitaxial layer 108 is formed in the base of the memory hole MH, and this epitaxial layer 108 is connected to a lower end of the semiconductor layer 23 configuring a channel portion of the memory string MS. As a result, a sufficient cell current can be obtained at the lower end of the memory string. Moreover, the concave portion 108E is formed in the surface of the epitaxial layer 108, and the insulating film core 101 is formed so as to penetrate inside this concave portion 108E. This makes it possible to suppress the leak current flowing in the center of the memory string MS far from the select transistor S2, during OFF operation of the select transistor S2.

### Second Embodiment

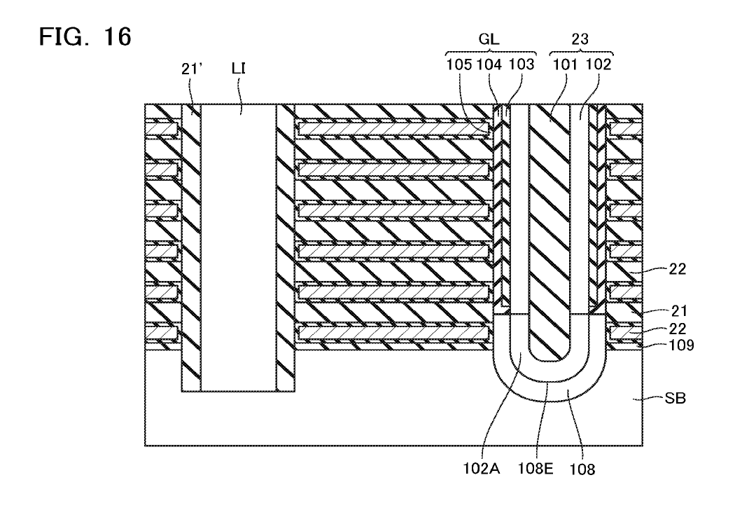

Next, a nonvolatile semiconductor memory device according to a second embodiment will be described with reference to FIG. 16. As shown in FIG. 16, the nonvolatile semiconductor memory device of this second embodiment differs from that of the first embodiment in a configuration of a lower end of the memory string MS. Other configurations (FIGS. 1 to 5) are substantially identical to those of the first embodiment, hence duplicated descriptions thereof will be omitted. Note that in FIG. 16, configuration elements identical to those of FIG. 6 are assigned with identical reference symbols to those assigned in FIG. 6, and detailed descriptions thereof will be omitted below.

This second embodiment differs from the first embodiment in having a solid phase epitaxial layer 102A formed inside the concave portion 108E of the epitaxial layer 108. This solid phase epitaxial layer 102A can be formed by setting appropriate amorphous deposition conditions and annealing conditions in the case where the semiconductor columnar portion 102 configured from polysilicon is formed by depositing an amorphous film similarly to in FIG. 13 and then executing annealing processing. That is, the solid phase epitaxial layer 102A is formed inside the concave portion 108E by solid phase epitaxial growth at the surface of the epitaxial layer 108 configured from monocrystalline silicon.

Due to the configuration of this second embodiment, similar advantages to those of the first embodiment are obtained. In addition, the solid phase epitaxial layer 102A makes it possible to further improve conductivity at the base of the memory string MS and to increase an ON current during conductivity of the select transistor S2.

### OTHERS

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a semiconductor substrate;
a semiconductor columnar portion extending in a perpendicular direction to the semiconductor substrate;
a memory gate insulating layer covering a side surface of the semiconductor columnar portion;
a stacked body disposed so as cover a periphery of the semiconductor columnar portion and including a conductive layer and an inter-layer insulating layer stacked alternately in a stacking direction on the semiconductor substrate; and
an epitaxial layer disposed on a surface of the semiconductor substrate and disposed so as to be electrically connected to a lower end of the semiconductor columnar portion,
the semiconductor columnar portion comprising:
an insulating film core; and
a semiconductor portion disposed so as to cover a periphery of the insulating film core and electrically connected to the epitaxial layer at a lower end portion,
the epitaxial layer including a concave portion in a surface thereof, and
the insulating film core having a lower end thereof positioned inside the concave portion.

2. The nonvolatile semiconductor memory device according to claim 1, wherein
the semiconductor portion is disposed at a position between the epitaxial layer and the insulating film core, inside the concave portion.

3. The nonvolatile semiconductor memory device according to claim 2, wherein
the semiconductor portion includes polysilicon.

4. The nonvolatile semiconductor memory device according to claim 1, wherein
the semiconductor portion has a crystalline structure which differs from that of the epitaxial layer.

5. The nonvolatile semiconductor memory device according to claim 1, wherein
the epitaxial layer includes monocrystalline silicon disposed continuously from monocrystalline silicon configuring the semiconductor substrate.

6. The nonvolatile semiconductor memory device according to claim 5, wherein
the semiconductor portion includes polysilicon.

7. The nonvolatile semiconductor memory device according to claim 1, further comprising:
a select transistor formed at the lower end of the semiconductor columnar portion,
wherein a gate electrode of one of the select transistors includes the plurality of conductive layers, and
the insulating film core has an end portion at a position of at least one of the plurality of conductive layers.

8. The nonvolatile semiconductor memory device according to claim 7, wherein
the semiconductor portion is disposed at a position between the epitaxial layer and the insulating film core, inside the concave portion.

9. The nonvolatile semiconductor memory device according to claim 1, further comprising:
a select transistor disposed below the semiconductor columnar portion,
wherein a gate electrode of one of the select transistors includes the plurality of conductive layers, and
the insulating film core has an end portion at a position of the lowermost layer conductive layer of the plurality of conductive layers.

10. The nonvolatile semiconductor memory device according to claim 9, wherein
the semiconductor portion is disposed at a position between the epitaxial layer and the insulating film core, inside the concave portion.

11. The nonvolatile semiconductor memory device according to claim 1, further comprising:
a solid phase epitaxial layer disposed between the epitaxial layer and the insulating film core and disposed continuously from the epitaxial layer, inside the concave portion.

12. The nonvolatile semiconductor memory device according to claim 11, wherein
the semiconductor portion includes polysilicon.

13. A nonvolatile semiconductor memory device, formed by:
forming a stacked body on a semiconductor substrate, the stacked body having a plurality of conductive layers stacked therein sandwiching an inter-layer insulating film;
forming a first hole that penetrates the stacked body and reaches the semiconductor substrate;
forming an epitaxial layer in a bottom of the first hole;
forming a memory gate insulating film on a side surface of the first hole, the memory gate insulating film including a charge accumulation layer;
forming a concave portion in a surface of the epitaxial layer; and
forming a semiconductor layer and an insulating layer in the first hole including inside the concave portion,
the insulating layer being formed also inside the concave portion.

14. The nonvolatile semiconductor memory device according to claim 13, wherein
the semiconductor layer is formed by depositing polysilicon.

15. The nonvolatile semiconductor memory device according to claim 13, wherein
the epitaxial layer is polycrystallized by depositing amorphous silicon and then executing annealing processing.

16. The nonvolatile semiconductor memory device according to claim 13, wherein
the nonvolatile semiconductor memory device comprises a select transistor disposed at a lower end of the semiconductor layer,
a gate electrode of one of the select transistors includes the plurality of conductive layers, and
the insulating layer is disposed so as to reach at least one of the plurality of conductive layers.

17. The nonvolatile semiconductor memory device according to claim 13, wherein
the semiconductor layer is disposed inside the concave portion by solid phase epitaxial growth using the epitaxial layer as an underlayer.

18. The nonvolatile semiconductor memory device according to claim 17, wherein
the semiconductor layer is disposed by depositing polysilicon.
